(19) United States
(12) Patent Application Publication
(10) Pub. No.: US 2007/0090500 A1
(43) Pub. Date: Apr. 26, 2007

(54) Housed DRAM chip for high-speed applications

(76) Inventor: Peter Poechmueller, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/581,068

(22) Filed: Oct. 16, 2006

(30) Foreign Application Priority Data
Oct. 14, 2005 (DE) 102005049248.7

(51) Int. Cl. H01L 23/495

(52) U.S. Cl. 257/666

(57) ABSTRACT

A housed DRAM chip includes a DRAM chip and a housing substrate. The DRAM chip is arranged on the housing substrate such that shorter conductive connections between the chip pads of the DRAM chip and external housing connections can be achieved for high data transmission speeds.

### CROSS REFERENCE TO RELATED APPLICATIONS

This application claims priority under 35 U.S.C. §119 to Application No. DE 102005049248.7 filed on Oct. 14, 2005, entitled “Housed Dram Chip for High-Speed Applications,” the entire contents of which are hereby incorporated by reference.

### BACKGROUND

Future DRAMs (Dynamic Random Access Memories) are intended to satisfy the ever increasing demands imposed on the speed when reading and writing data for high-speed applications such as graphics. Data and clock frequencies above 500 MHz are required for this purpose. Current chip pad and housing architectures constitute a considerable obstacle when implementing such high-speed DRAMs since the signals between the chip pads and external housing connections are subject to a parasitic RLC delay on account of the electrical connection which is between them and is produced using bonding wires, for example. Known DRAMs have chip pads which are arranged either along a first major chip axis or a second major chip axis or along the chip edges. Chip pads which are arranged along the major chip axes in FBGA (Fine Ball Grid Array) housings are connected to the external housing connections of the housing via housing substrate openings along the major housing substrate axes and relatively long bonding wires. This results in the propagation time delays when interchanging data. One possible way of increasing the speed of a memory access operation is to improve the chip/housing architecture in order to reduce the signal delay between the external housing connection and the chip pad.

It would be beneficial to specify a housed DRAM which enables reduced signal propagation times between the external housing connections and the chip pads and is thus suitable for high-speed applications of future memory generations.

### SUMMARY

A housed DRAM chip includes a DRAM chip and a housing substrate. The DRAM chip is arranged on the housing substrate such that shorter conductive connections between the chip pads of the DRAM chip and external housing connections can be achieved for high data transmission speeds.

The above and still further features and advantages of the described device will become apparent upon consideration of the following definitions, descriptions and descriptive figures of specific embodiments thereof, wherein like reference numerals in the various figures are utilized to designate like components. While these descriptions go into specific details of the described device, it should be understood that variations may and do exist and would be apparent to those skilled in the art based on the descriptions herein.

### BRIEF DESCRIPTION OF THE DRAWINGS

Some embodiments of the described device and, in particular, certain aspects and advantages of the described device are illustrated with reference to the following detailed description in conjunction with the accompanying drawings, where:

FIG. 1 shows a first example of a known housed DRAM;

FIG. 2 shows a second example of a known housed DRAM;

FIG. 3 shows a plan view of a DRAM chip including a known pad architecture;

FIG. 4 shows a plan view of an ideal arrangement of chip pads and external housing connections for high-speed applications;

FIG. 5 shows a plan view of a chip pad arrangement of a first embodiment of a housed DRAM chip;

FIG. 6 shows a plan view of a chip pad arrangement of a second embodiment of a housed DRAM chip;

FIG. 7 shows a schematic cross-sectional view of a housed DRAM chip of a known type;

FIG. 8 shows another schematic cross-sectional view of a housed DRAM chip of a known type;

FIG. 9 shows a plan view of housing substrates having known housing substrate openings;

FIG. 10 shows a plan view of a chip pad arrangement for high-speed applications for DRAMs;

FIG. 11 shows a plan view of a housing substrate according to a third embodiment of a housed DRAM chip;

FIG. 12 shows a schematic plan view of a housing substrate of a fourth embodiment of a housed DRAM chip;

FIG. 13 shows a schematic plan view of a housing substrate of a fifth embodiment of a housed DRAM chip;

FIG. 14 shows a schematic plan view of a housing substrate of a sixth embodiment of a housed DRAM chip; and

FIG. 15 shows a schematic plan view of a housing substrate having two DRAM chips of a seventh embodiment of a housed DRAM chip.

### DETAILED DESCRIPTION

A housed DRAM chip for clock frequencies above 500 MHz includes: a chip housing with external housing connections and a housing substrate, a DRAM chip which is arranged on the housing substrate, chip pads that are arranged on a surface of the DRAM chip, bonding wires for wiring the chip pads to the external housing connections, a first major chip axis which extends parallel to one of the chip edges along the surface through the center of the DRAM chip, a second major chip axis which extends perpendicular to the first major chip axis along the surface through the center of the chip, a first major housing substrate axis which extends parallel to a housing substrate edge and a housing substrate surface through the center of the housing substrate, a second major housing substrate axis which extends perpendicular to the first major housing substrate axis through the center of the housing substrate and parallel to the housing substrate surface, at least one of the chip pads being arranged outside a chip edge surface region and outside a first major chip axis surface region and a second major chip axis surface region in a further chip surface region. The chip edge surface region extends along the chip edges with a width of 5% of the distance between a respective chip edge and an opposite chip edge, and the first and second major chip axis surface regions respectively extend symmetrically along the corresponding major chip axis with a width of 10% of the distance between two chip edges which run parallel to the corresponding major chip axis. The DRAM chip and the housing substrate have a rectangular basic shape, for example. Current chip pad architectures of DRAMs arrange the chip pads in the first and second major chip axis surface regions and in the chip edge surface region in order to be compatible with housing substrates which have been standardized in accordance with Joint Electron Device Engineering Council (JEDEC) standards. However, arranging the chip pads in the further chip surface region makes it possible to achieve a shorter line between the chip pad and the associated housing connection, thus resulting in higher transmission speeds.

In one embodiment, some of the chip pads are arranged in the further surface region along first minor axes which run parallel to the first major chip axis. These chip pads are thus arranged outside the major chip axes, thus making it possible to achieve shorter lines between the chip pad and the external housing connection compared with the above known chip pad architecture.

Some of the chip pads are DQ pads. The DQ pads are chip pads are subjected to the greatest speed requirements on the DRAM and are used to interchange data bits. The greatest demands are imposed on signal transmission speeds for such chip pads, in particular. Besides DQ pads, the greatest speed demands are likewise imposed on clock signal pads (CLK pads), for example.

Another embodiment is distinguished by first minor axes which run parallel to bit lines of memory cell arrays of the DRAM chip. The first minor axes run outside memory cell arrays and may be used, for example, to arrange chip pads in order to optimize the signal speeds to external housing connections.

In another embodiment, each of the memory cell arrays is divided into sub memory cell arrays which run parallel to bit lines and have the first minor axes which run between the sub memory cell arrays. Dividing the memory cell arrays into sub memory cell arrays provides additional possible ways of optimizing the chip pad architecture as regards higher signal speeds to external housing connections.

2ⁿ first minor axes can run in each half of the DRAM chip, n being an integer greater than or equal to zero.

In another embodiment, some of the chip pads are arranged in the further surface region along second minor axes which run parallel to the second major chip axis. These chip pads are thus arranged outside the major chip axes, thereby making it possible to achieve shorter lines between the chip pad and the external housing connection compared with the above known chip pad architecture.

Those chip pads which are arranged along the second minor axes can be DQ pads.

The second minor axes preferably run parallel to word lines of memory cell arrays of the DRAM chip.

It can be of advantage if each of the memory cell arrays is divided into sub memory cell arrays which run parallel to word lines and have the second minor axes which run between the sub memory cell arrays. Dividing the memory cell arrays into sub memory cell arrays provides additional possible ways of optimizing the chip pad architecture as regards higher signal speeds to external housing connections.

Another embodiment of a housed DRAM chip having clock frequencies above 500 MHz comprises a chip housing including external housing connections and a housing substrate, a DRAM chip which is arranged on the housing substrate, chip pads which are arranged on a surface of the DRAM chip, bonding wires for wiring the chip pads to the external housing connections, a major chip axis which extends parallel to one of the chip edges along the surface through the center of the chip, a second major chip axis which extends perpendicular to the first major chip axis along the surface through the center of the chip, a first major housing substrate axis which extends parallel to a housing substrate edge of a housing surface through the center of the housing substrate, a second major housing substrate axis which extends perpendicular to the first major housing substrate axis through the center of the housing substrate and parallel to the housing substrate surface, one or more housing substrate openings or parts of the latter being formed outside a first main housing substrate surface region and outside a second main housing substrate surface region in a further housing substrate surface region. In this case, the first and second main housing substrate surface regions respectively extend symmetrically along the corresponding major housing substrate axis with a width of at most 4 mm. Known housing substrates for DRAMs have housing substrate openings only inside the first and second main housing substrate surface regions. Forming housing substrate openings outside these regions as well results in various possible ways of connecting DRAM chips to the external housing connections via short lines in the case of a face-down arrangement in order to achieve fast signal speeds.

It can be of advantage to form at least one housing substrate opening in a curved manner in one or more partial regions of the housing substrate opening. It is conceivable to design the housing substrate openings to be elliptical or else round, to name just a few examples.

In one embodiment, at least one housing substrate opening is formed parallel to the first or second major housing substrate axis in the further housing substrate surface region.

The housing substrate preferably has at least three housing substrate openings. This plurality of housing substrate openings gives rise to high flexibility as regards an optimum arrangement of chip pads on the DRAM chip and bonding wires for the shortest possible signal delays on the lines to the external housing connections.

In one embodiment, the housed DRAM chip includes at least one housing substrate opening having at least three edges, the bonding wires which pass through the housing substrate opening crossing more than two edges. This allows a large number of chip pads to be wired for each housing substrate opening, which constitutes a considerable advantage, in particular when the chip pads, housing substrate opening and external housing connections are oriented in an optimized manner.

It can be of advantage to form a housing substrate opening in the form of a dumbbell. This opening has the shape of an “H”. If the dumbbell-shaped housing substrate opening is combined with bonding wires which cross more than two edges of the dumbbell-shaped openings, it is advantageously possible to connect a plurality of chip pads to the external housing connections via lines which have been optimized as regards the signal propagation times.

In one embodiment, a housing substrate opening has at least two axes of symmetry along the housing substrate surface.

It can be of advantage if two of the axes of symmetry are perpendicular to one another.

In one embodiment, at least one housing substrate opening opens the housing substrate from a housing substrate border. Such a housing substrate opening is thus not completely surrounded by the housing substrate but rather engages in the housing substrate from a housing substrate edge.

The housing substrate advantageously has more than four edges. Such a housing substrate can be realized, for example, using a housing substrate opening which opens the housing substrate starting from a housing substrate border or else may be realized using a housing substrate without interrupted housing substrate edges such as an octahedral housing substrate.

In another embodiment, at least eight chip pads are respectively arranged directly above an external housing connection which is connected to the corresponding pad. These chip pads are thus located vertically above the associated external housing connections. The corresponding chip pads are preferably chip pads subjected to the highest speed requirements, for instance DQ chip pads or CLK chip pads. This optimum arrangement of the chip pad and the external housing connection makes it possible to achieve very fast signal transmission speeds.

The DRAM chip is advantageously applied to the housing substrate surface using the surface including the chip pads. Such an arrangement is also referred to as a face-up arrangement.

In another embodiment, the DRAM chip is applied to the housing substrate surface using the surface opposite to the surface including the chip pads. Such an arrangement is also referred to as a face-down arrangement.

It is advantageous that the DRAM chip and a further DRAM chip are arranged parallel to a housing substrate edge and adjacent to one another above a respective housing substrate opening. This makes it possible to achieve preferred arrangements of chip pads and external housing connections at different locations on the housing substrate with the aid of the respective openings.

The arrangements of chip pads in the further chip surface region and of housing substrate openings in the further housing substrate surface region can be combined in various ways in order to achieve short connections from the chip pad to the external housing connection.

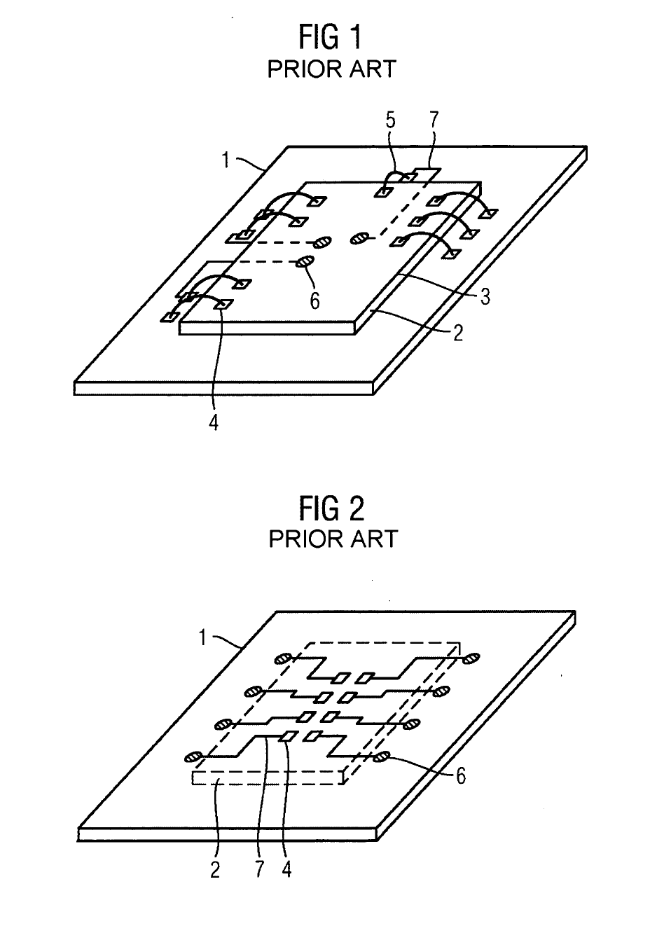

Exemplary embodiments of the invention are described in connection with the figures. FIG. 1 schematically illustrates a first example of a known housed DRAM. A DRAM chip 2 is arranged on a housing substrate 1. A plurality of chip pads 4 have been placed (schematically illustrated) on a surface 3 of the DRAM chip 2. The chip pads 4 run along a chip edge surface region. Chip pads 4 which have been arranged in this manner are compatible with external housing plans which have been standardized in accordance with JEDEC. The chip pads 4 and the housing substrate 1 are conductively connected using bonding wires 5. There is a conductive connection 7 between the bonding wires 5, which are connected to the housing substrate 1, and external housing connections 6. An arrangement of the housing substrate 1 and the DRAM chip 2 as illustrated in FIG. 1 is also referred to as a face-up arrangement since the DRAM chip 1 is applied to the housing substrate 1 using that surface which is opposite the surface 3 including the chip pads 4. For the sake of clarity, no additional components of the chip housing, apart from the housing substrate 1 and the external connections 6, are shown in this figure and in the other figures.

FIG. 2 shows a view of a housed DRAM in a flip-chip housing which is intended to be used for future DRAMs. Chip pads 4 are arranged, by way of example, along a major chip axis. As was already the case in the previous example described in FIG. 1, the DRAM chip 2 is situated on the housing substrate 1. However, in contrast to the previous example, the DRAM chip 2 is applied to the housing substrate 1 using the surface 3 which includes the chip pads 4. An arrangement of this type is also referred to as a face-down arrangement. The chip pads 4 are conductively connected (not illustrated) to the housing substrate 1 with the aid of solder contact bumps. The conductive connections 7 are used to connect the chip pads 4 to the external housing connections 6. In contrast to the previous embodiment, this flip-chip arrangement does not require any bonding wires to conductively connect the chip pads to the housing substrate 1. Nevertheless, the conductive connections 7 to the external housing connections 6 entail considerable signal delays on account of their length.

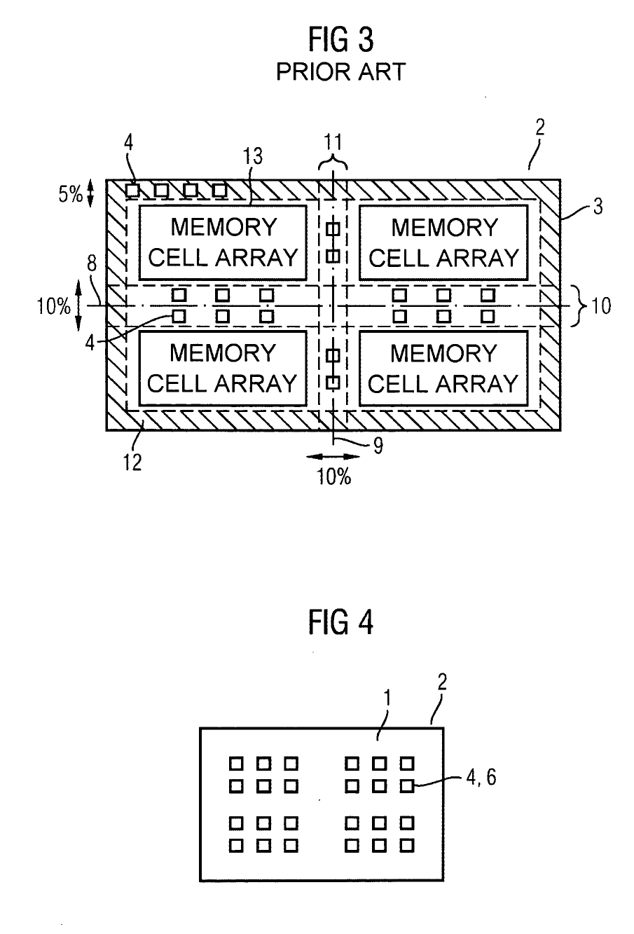

FIG. 3 shows a plan view of the surface 3 of a DRAM chip including a known chip pad architecture. Some of the chip pads 4 are arranged (schematically illustrated) along a first major chip axis 8, which runs through the center of the DRAM chip 2, and parallel to a chip edge. Further chip pads 4 are also situated along a second major chip axis 9 which is perpendicular to the first major chip axis 8 and likewise runs through the center of the DRAM chip 2. The chip pads 4 which are arranged along the first and second major chip axes 8, 9 are situated within first and second major chip axis surface regions 10, 11. Some of the chip pads are also placed along the chip edges in a chip edge surface region 12. For the sake of clarity, only some of the chip pads 4 are shown in the illustration. Memory cell arrays 13 are situated outside the first and second major chip axis surface regions 10 and 11 and outside the chip edge surface region 12. The chip pads in current DRAM chips are arranged in the surface regions 10, 11 and 12. The first major chip axis surface region 10 and the second major chip axis surface region 11 have a width corresponding to 10% of the distance between the chip edges which are parallel to the corresponding first and second major chip axes 8, 9. The chip edge surface region 12 also has a width of 5% of the distance between the chip edges which are respectively opposite one another. A chip pad configuration of this type is compatible with external housing dimensions in accordance with the JEDEC standard.

It should be pointed out that surface regions which are indicated in the figures are not represented to scale for the sake of clarity.

FIG. 4 shows a plan view of an ideal arrangement for chip pads 4 of a DRAM chip 2 and external housing connections 6. In this case, the chip pads 4 are directly above corresponding housing connections, which are shown in the illustration using a locally joint reference for the chip pads 4 and housing connections 6. The external housing connections 6 and chip pads 4 which are vertically above one another make it possible for the parasitic delay times between the chip pads 4 and the external housing connections 6 to be considerably shortened for high-speed signals such as clock or data signals (DQ and CLK signals) on account of the short line paths in comparison with known arrangements.

FIG. 5 illustrates a plan view of a surface 3 of an arrangement of chip pads 4 according to a first embodiment of a housed DRAM chip 2. For the sake of clarity, wiring to a housing substrate is not shown. The DRAM chip 2 has a first major chip axis 8 and a second major chip axis 9. In contrast to the known arrangement of chip pads 4 and memory cell arrays 13 shown in FIG. 3, the first embodiment has memory cell arrays which have been divided into sub memory cell arrays 14. In this case, the memory cell arrays were divided along second minor axes 15 which are parallel to the second major chip axis 9. The sub memory cell arrays 14 are arranged on the DRAM chip 2 in such a manner that their word lines 18 are also parallel to the second minor axes 15 and the second major chip axis 9. Bit lines 19 of the DRAM chip are correspondingly perpendicular to the word lines 18 and thus parallel to the first major chip axis 8. DQ chip pads 16, on which the greatest speed demands are imposed when interchanging data with the DRAM chip 2, are located along the second minor axes 15 and thus between the sub memory cell arrays 14. The DQ chip pads 16 are thus placed in a further chip surface region 17 outside the first and second major chip axis surface regions 10, 11 and outside the chip edge surface region 12. Although such an arrangement of the DQ chip pads 16 cannot be used to achieve optimum matching between the pads and the associated external housing connections, it nevertheless makes it possible to considerably reduce the parasitic delay of the signals between the pad and the external housing connection since the length of an associated line connection can be considerably reduced in comparison with a known pad arrangement, for instance in FIG. 3.

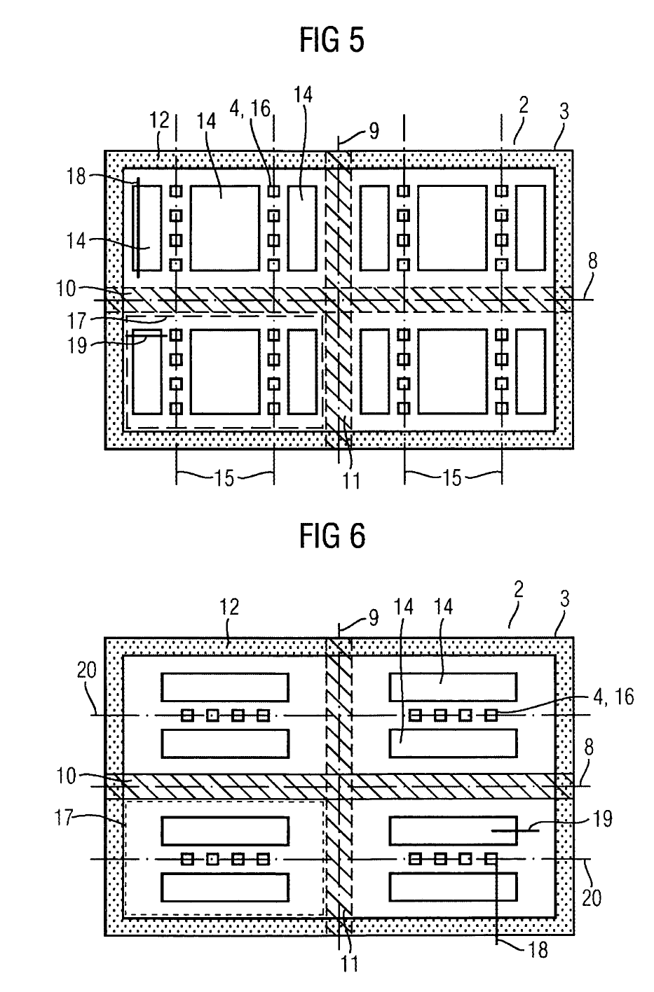

FIG. 6 illustrates a plan view of a surface 3 of an arrangement of chip pads 4 according to a second embodiment of a housed DRAM chip 2. For the sake of clarity, wiring to a housing substrate is not illustrated, as in FIG. 5. The DRAM chip 2 has a first major chip axis 8 and a second major chip axis 9. As in the first embodiment in FIG. 5, the memory cell arrays have been divided into sub memory cell arrays 14. However, in contrast to the first embodiment, the memory cell arrays were divided along first minor axes 20 which are parallel to the first major chip axis 8. The sub memory cell arrays 14 are arranged on the DRAM chip 2 in such a manner that the word lines 18 are again parallel to the second major chip axis 9. The bit lines 19 of the DRAM chip are correspondingly perpendicular to the word lines 18 and thus parallel to the first major chip axis 8 and the first minor axes 20. DQ chip pads 16 are located along the first minor axes 20 and thus between the sub memory cell arrays 14. The DQ chip pads 16 are thus placed in a further chip surface region 17 outside the first and second major chip axis surface regions 10, 11 and outside the chip edge surface region 12. Although such an arrangement of the DQ chip pads 16 again cannot be used to achieve optimum matching between the pads and the associated external housing connections, this embodiment also makes it possible to considerably reduce the parasitic delay of the signals between the pad and the external housing connection since the length of an associated line connection can be considerably reduced in comparison with a known pad arrangement, for instance in FIG. 3.

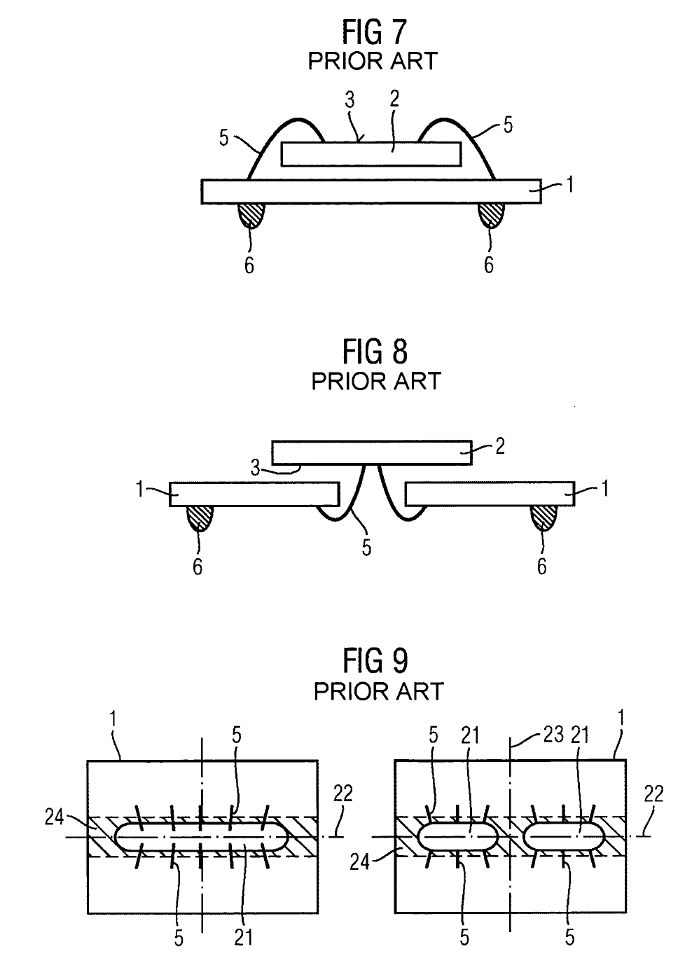

FIG. 7 illustrates a schematic cross-sectional view of a housed DRAM chip 2 of a known type. In this case, the DRAM chip 2 is applied to a housing substrate 1 including external housing connections 6 using a surface of the DRAM chip 2 which is opposite the surface 3 including the chip pads 4. The DRAM chip 2 and the housing substrate 1 are conductively connected with the aid of bonding wires 5 which are connected to corresponding chip pads 4 in the chip edge surface region 12 of the DRAM chip 2 (not illustrated in FIG. 7, see FIG. 1 for instance). Current Synchronous Dynamic Random Access Memories (SDRAMs), for example, are based on such an arrangement of the DRAM chip 2 and the housing substrate 1. This arrangement is also referred to as a face-up arrangement.

If the chip pads 4 are placed along one of the major chip axes 8, 9, as is illustrated, for example, in FIG. 2, the corresponding DRAM chips 2 are applied to the housing substrate as shown in FIG. 8. In this case, the DRAM chip 2 is applied to the housing substrate 1 using the surface 3 which has the chip pads 4, which is also referred to as a face-down arrangement. The chip pads 4 and the housing substrate 1 are conductively connected using bonding wires 5 which are routed through a housing substrate opening 21 lying along a major housing substrate axis. It should be noted that, in the case of such an arrangement, the bonding wires 5 cross only two edges of the housing substrate opening 21, both of these edges being illustrated in the schematic cross-sectional view. Edges of the housing substrate opening 21 which are parallel to the plane of the drawing are consequently not crossed by bonding wires 5. FIG. 2, for example, provides a further view of the arrangement illustrated in FIG. 8.

FIG. 9 shows plan views of housing substrates 1 having known housing substrate openings 21. For the sake of simplicity, no external housing connections 6 are illustrated but they can be seen in conjunction with such a housing substrate 1 in FIG. 8, for example. The housing substrates 1 have a first major housing substrate axis 22 and a second major housing substrate axis 23, the housing substrate opening(s) 21 each being formed along the first major housing substrate axis 22 within a first main housing substrate surface region 24. In comparison with the illustration in FIG. 8, it becomes more obvious from this plan view that, in the case of the known housed DRAM chip, the bonding wires 5 cross only two of the four edges of a respective housing substrate opening 21.

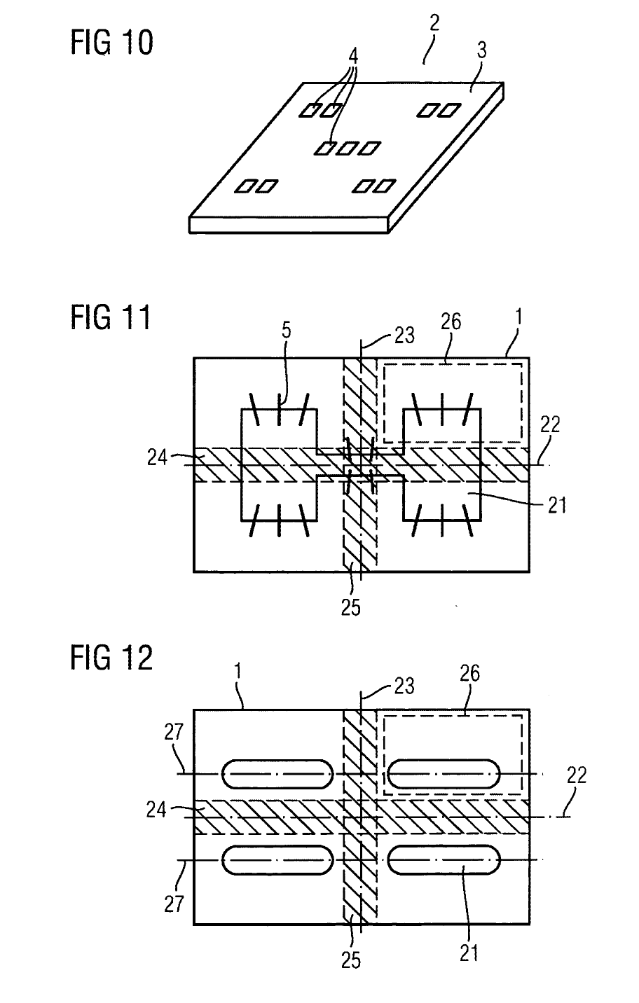

FIG. 10 shows a plan view of a DRAM chip 2 including chip pads 4 which, in comparison with the known positioning of the chip pads 4 in the first and second major chip axis surface regions 10, 11 or the chip edge surface region 12 as shown in FIG. 3, are also placed outside these regions. Such pad architecture makes it possible to shorten the lines between the chip pads 4 and the external housing connections 6 (not illustrated) and thus enables higher data transmission speeds.

The plan view illustrated in FIG. 11 shows a housing substrate 1 including a housing substrate opening 21 according to a third embodiment of a housed DRAM chip. For the sake of clarity, the DRAM chip 2 is not illustrated. However, the latter is located behind the plane of the drawing, as can be gathered from the course of the bonding wires 5. The housing substrate opening 21 in the housing substrate 1 has the shape of a dumbbell and also extends, outside the first and second main housing substrate surface regions 24, 25, into a further housing substrate surface region 26 thereby enabling the greatest possible flexibility as regards to an optimum arrangement of the chip pads 4 (not illustrated) with respect to the external housing connections. In particular, in contrast to the known bonding wire arrangement from FIG. 9, the bonding wires cross more than two mutually opposite edges of the housing substrate opening 21.

FIG. 12 illustrates a plan view of a housing substrate 1 including a housing substrate opening 21 according to a fourth embodiment of a housed DRAM chip. In this fourth embodiment, four housing substrate openings 21 are formed, the openings being arranged along two further housing substrate axes 27, which run parallel to the first major housing substrate axis 22, and also extending within the further housing substrate surface region 26. This embodiment also makes it possible to shorten the line length between the chip pads and the external housing substrate connections and thus enables faster data transmission rates on the corresponding pins.

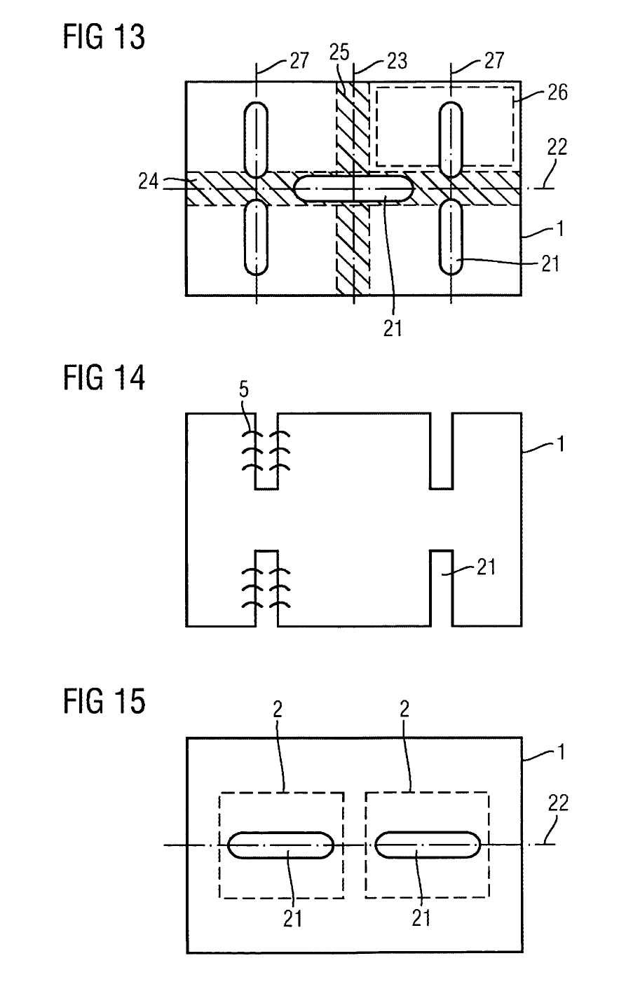

FIG. 13 illustrates a plan view of a housing substrate 1 including a plurality of housing substrate openings 21 according to a fifth embodiment of a housed DRAM chip. Bonding wires to a DRAM chip are not illustrated for the sake of clarity. The housing substrate openings 21 may be arranged along the first major housing substrate axis 22 and may be also arranged along further housing substrate axes 27 which run parallel to the second major housing substrate axis 23. Some of the housing substrate openings 21 are thus located along axes, which are perpendicular to one another, and also within the further housing substrate surface region.

FIG. 14 shows a schematic plan view of a housing substrate 1 including a plurality of housing substrate openings 21 according to a sixth embodiment of a housed DRAM chip. The housing substrate 1 of the sixth embodiment includes housing substrate openings 21 which open the housing substrate 1 starting from a housing substrate border. In this embodiment, for instance, an originally rectangular housing substrate including four housing substrate edges thus becomes a housing substrate including more than four housing substrate edges. The bonding wires 5 are again used to connect the chip pads 4 (not illustrated) to the housing substrate 1.

FIG. 15 is a schematic plan view of a housing substrate 1 including two housing substrate openings 21 which extend along the first major housing substrate axis 22. A DRAM chip 2, which is respectively illustrated in the figure using dashed lines, is respectively arranged above the two housing substrate openings 21. The DRAM chips 2 are arranged next to one another extending along the first major housing substrate axis 22. This makes it possible for chip pads of the two DRAM chips 2 to be driven using high-speed signals by virtue of two different positions on the housing substrate 1 with the aid of the two housing substrate openings 21 and bonding wires which are not illustrated in FIG. 15.

While the device has been described in detail with reference to specific embodiments thereof, it will be apparent to one of ordinary skill in the art that various changes and modifications can be made therein without departing from the spirit and scope thereof. Accordingly, it is intended that the described device covers the modifications and variations of this device provided they come within the scope of the appended claims and their equivalents.

What is claimed is:

1. A housed DRAM chip comprising:
a chip housing including external housing connections and a housing substrate;
a DRAM chip arranged on the housing substrate and including memory cell arrays with word lines and bit lines, each of the memory cell arrays being divided into sub memory cell arrays such that the sub memory cell arrays run parallel to the bit lines and include first minor axes, wherein the first minor axes run between the sub memory cell arrays;
chip pads arranged on a surface of the DRAM chip, at least one of the chip pads being arranged along the first minor axes and between adjacent sub memory cell arrays, wherein at least one of the chip pads is a DQ chip pad; and
bonding wires for wiring the chip pads to the external housing connections.

2. The housed DRAM chip according to claim 1, wherein the first minor axes run parallel to bit lines of memory cell arrays of the DRAM chip.

3. The housed DRAM chip according to claim 1, wherein 2ⁿ first minor axes run in each half of the DRAM chip, where n≧0.

4. The housed DRAM chip according to claim 1, wherein at least eight chip pads are respectively arranged directly above and connected to an external housing connection.

5. The housed DRAM chip according to claim 1, wherein the surface of the DRAM chip, that includes the chip pads, is applied to a housing substrate surface.

6. The housed DRAM chip according to claim 1, wherein the surface of the DRAM chip, that is opposite the surface including the chip pads, is applied to a housing substrate surface.

7. The housed DRAM chip according to claim 1, wherein the DRAM chip and a further DRAM chip are arranged adjacent to one another, above a respective housing substrate opening, and parallel to a housing substrate edge.

8. A housed DRAM chip comprising:
a chip housing including external housing connections and a housing substrate;
a DRAM chip arranged on the housing substrate and including memory cell arrays with word lines and bit lines, each of the memory cell arrays being divided into sub memory cell arrays such that the sub memory cell arrays run parallel to word lines and include second minor axes, wherein the second minor axes run between the sub memory cell arrays;
chip pads being arranged on a surface of the DRAM chip, at least one of the chip pads being arranged along the second minor axes and between adjacent sub memory cell arrays, wherein at least one of the chip pads is a DQ chip pad; and
bonding wires for wiring the chip pads to the external housing connections.

9. The housed DRAM chip according to claim 8, wherein the second minor axes run parallel to word lines of memory cell arrays of the DRAM chip.

10. The housed DRAM chip according to claim 8, wherein 2ⁿ second minor axes run in each half of the DRAM chip, where n≧0.

11. The housed DRAM chip according to claim 8, wherein at least eight chip pads are respectively arranged directly above and connected to an external housing connection.

12. The housed DRAM chip according to claim 8, wherein the surface of the DRAM chip, that includes the chip pads, is applied to a housing substrate surface.

13. The housed DRAM chip according to claim 8, wherein the surface of the DRAM chip, that is opposite the surface including the chip pads, is applied to a housing substrate surface.

14. The housed DRAM chip according to claim 8, wherein the DRAM chip and a further DRAM chip are arranged adjacent to one another, above a respective housing substrate opening, and parallel to a housing substrate edge.

15. A housed DRAM chip comprising:
a chip housing including external housing connections and a housing substrate with at least one opening;
a DRAM chip arranged on the housing substrate;
chip pads are arranged on a surface of the DRAM chip; and
bonding wires for wiring the chip pads to the external housing connections.

16. The housed DRAM chip according to claim 15, wherein the at least one housing substrate opening includes at least three edges, and wherein the bonding wires pass through the at least one opening and cross more than two edges of the at least one opening.

17. The housed DRAM chip according to claim 15, wherein the at least one housing substrate opening extends to a housing substrate border.

18. The housed DRAM chip according to claim 15,
wherein the at least one housing substrate opening extends to a housing substrate border and includes at least three edges; and
wherein the bonding wires pass through the at least one opening and cross more than two edges of the at least one housing substrate opening.

19. The housed DRAM chip according to claim 15, wherein the housing substrate includes at least three housing substrate openings.

20. The housed DRAM chip according to claim 15, wherein at least one housing substrate opening is in the shape of a dumbbell.

21. The housed DRAM chip according to claim 15, wherein at least one housing substrate opening has at least two axes of symmetry along a housing substrate surface.

22. The housed DRAM chip according to claim 21, wherein the two axes of symmetry are perpendicular to one another.

23. The housed DRAM chip according to claim 15, wherein the housing substrate includes more than four edges.

24. The housed DRAM chip according to claim 15, wherein at least eight chip pads are respectively arranged directly above and connected to an external housing connection.

25. The housed DRAM chip according to claim 15, wherein the surface of the DRAM chip, that includes the chip pads, is applied to a housing substrate surface.

26. The housed DRAM chip according to claim 15, wherein the surface of the DRAM chip, that is opposite the surface including the chip pads, is applied to a housing substrate surface.

27. The housed DRAM chip according to claim 15, wherein the DRAM chip and a further DRAM chip are arranged adjacent to one another, above a respective housing substrate opening, and parallel to a housing substrate edge.

28. A housed DRAM chip comprising:
a chip housing including external housing connections and a housing substrate;
a DRAM chip arranged on the housing substrate;
chip pads arranged on a surface of the DRAM chip;
bonding wires for wiring the chip pads to the external housing connections;
a first major chip axis extending parallel to one of the chip edges along the surface through the center of the DRAM chip;
a second major chip axis extending perpendicular to the first major chip axis along the surface through the center of the DRAM chip;
a first major housing substrate axis extending parallel to a housing substrate edge and a housing substrate surface through the center of the housing substrate;
a second major housing substrate axis extending perpendicular to the first major housing substrate axis through the center of the housing substrate and parallel to the housing substrate surface; and
at least one housing substrate opening at least partially formed outside a first main housing substrate surface region and outside a second main housing substrate surface region in a further housing substrate surface region, the first and second main housing substrate surface regions respectively extending symmetrically along the corresponding major housing substrate axis with a width of at most 4 mm;
wherein the at least one housing substrate opening extends to a housing substrate border.

29. The housed DRAM chip according to claim 28, wherein at least one housing substrate opening is formed parallel to the first or second major housing substrate axis in the further housing substrate surface region.

30. A housed DRAM chip comprising:
a chip housing including external housing connections and a housing substrate;
a DRAM chip arranged on the housing substrate;
chip pads arranged on a surface of the DRAM chip;
bonding wires for wiring the chip pads to the external housing connections;
a first major chip axis extending parallel to one of the chip edges along the surface through the center of the DRAM chip;
a second major chip axis extending perpendicular to the first major chip axis along the surface through the center of the DRAM chip;
a first major housing substrate axis extending parallel to a housing substrate edge and a housing substrate surface through the center of the housing substrate;
a second major housing substrate axis extending perpendicular to the first major housing substrate axis through the center of the housing substrate and parallel to the housing substrate surface;
at least one housing substrate opening at least partially formed outside a first main housing substrate surface region and outside a second main housing substrate surface region in a further housing substrate surface region, the first and second main housing substrate surface regions respectively extending symmetrically along the corresponding major housing substrate axis with a width of at most 4 mm;
wherein the at least one housing substrate opening including at least three edges, and wherein the bonding wires pass through the at least one opening and cross more than two edges of the at least one housing substrate opening.

31. The housed DRAM chip according to claim 30, wherein at least one housing substrate opening is formed parallel to the first or second major housing substrate axis in the further housing substrate surface region.
